(19) United States
(12) Patent Application Publication
(10) Pub. No.: US 2009/0026486 A1
(43) Pub. Date: Jan. 29, 2009

(54) Nitride based compound semiconductor light emitting device and method of manufacturing the same

(75) Inventor: Osamu Jinushi, Higashihiroshima-shi (JP)

Correspondence Address: HARNESS, DICKEY & PIERCE, P.L.C., P.O. BOX 8910, RESTON, VA, 20195, US

(73) Assignee: SHARP KABUSHIKI KAISHA

(21) Appl. No.: 12/219,611

(22) Filed: Jul. 24, 2008

(30) Foreign Application Priority Data
Jul. 26, 2007 (JP) 2007-194282 (P)
May 30, 2008 (JP) 2008-142705 (P)

(51) Int. Cl. H01L 33/00

(52) U.S. Cl. 257/99; 438/33; 257/E33.023; 257/E33.063

(57) ABSTRACT

A nitride based compound semiconductor light emitting device having a first substrate and a nitride based compound semiconductor part including a p-type nitride based compound semiconductor layer, an active layer, and an n-type nitride based compound semiconductor layer in this order from the first substrate side, in which the first substrate has a through hole penetrating through the first substrate in up and down directions and a metal film is buried in the through hole, and its method of manufacturing. The heat dissipation property is improved in the nitride based compound semiconductor light emitting device.

This nonprovisional application is based on Japanese Patent Application No. 2007-194282 filed on Jul. 26, 2007 and No. 2008-142705 filed on May 30, 2008, with the Japan Patent Office, the entire contents of which are hereby incorporated by reference.

### BACKGROUND OF THE INVENTION

1. Field of the Invention

The present invention relates to a nitride based compound semiconductor light emitting device, and more particularly, to a nitride based compound semiconductor light emitting device having improved heat dissipation properties. Further, the present invention relates to a method of manufacturing the nitride based compound semiconductor light emitting device.

2. Description of the Background Art

A nitride based compound semiconductor light emitting device having a structure capable of taking out electrodes from above and below for improvement of heat dissipation properties of the device has been conventionally proposed (for example, Japanese Patent Laying-Open No. 2000-277804). FIG. 5 is a schematic cross-sectional view showing the structure of the nitride based compound semiconductor light emitting device disclosed in Japanese Patent Laying-Open No. 2000-277804. The nitride based compound semiconductor light emitting device shown in FIG. 5 can be obtained by adhering a conductive substrate 505 using a first ohmic electrode 503 and a second ohmic electrode 504 onto a wafer of a layered semiconductor 510 of a nitride based compound semiconductor layer in which an n-type layer 500, a light emitting layer 501, and a p-type layer 502 are layered one by one on an insulative substrate (not shown in the drawing), removing the insulative substrate, and exposing layered semiconductor 510 of the nitride based compound semiconductor layer. A negative electrode 506 and a positive electrode 507 are provided, as corresponding electrodes, to exposed layered semiconductor 510 and conductive substrate 505, respectively.

However, the conventional nitride based compound semiconductor light emitting device has a conductive substrate, in which GaAs, GaP, InP, Si, SiC, or the like is used, and therefore has a structure that is inferior in heat dissipation properties compared with a metal substrate having good thermal conductivity. In particular, in the case of using the light emitting device for a large current use, there is a possibility of causing a decrease of chip reliability and light emitting efficiency due to the low heat dissipation properties.

### SUMMARY OF THE INVENTION

The present invention is to solve the above-described problems, and an object of the present invention is to provide a nitride based compound semiconductor light emitting device having improved heat dissipation properties, and a method of manufacturing the same.

The present invention provides a nitride based compound semiconductor light emitting device having a first substrate and a nitride based compound semiconductor part including a p-type nitride based compound semiconductor layer, an active layer, and an n-type nitride based compound semiconductor layer in this order from the first substrate side, in which the first substrate has a through hole penetrating through the first substrate in a vertical direction and a metal film is buried in the through hole.

Here, each of the electrical conductivity and the thermal conductivity of the above-described metal film are preferably larger than the electrical conductivity and the thermal conductivity of a material constituting the above-described first substrate.

The above-described metal film is preferably formed from one or more kinds of metals selected from the group consisting of Cu, Ag, Au, Ni, Pd, and Al.

Further, the above-described first substrate preferably has conductive properties, and in this case, the first substrate is more preferably formed from a material selected from the group consisting of Si, GaAs, GaP, InP, and SiC. Further, the first substrate is not limited to substrates having conductive properties, and may be a substrate having nonconductive properties. Examples of the material constituting the first substrate having nonconductive properties include sapphire, AlN, and the like. The thickness of the first substrate is preferably 10 to 500 μm.

The thickness of the above-described first substrate is preferably the same as the thickness of the above-described metal film or thicker than that of the metal film.

Further, the nitride based compound semiconductor light emitting device in the present invention preferably has a protective layer at least between the inner wall surface of the above-described through hole and the sidewall surface of the above-described metal film.

The above-described n-type nitride based compound semiconductor layer preferably has unevenness at least one part of its surface. Further, the nitride based compound semiconductor light emitting device in the present invention preferably has an n-type electrode on the surface of the above-described n-type nitride based compound semiconductor layer.

Further, the present invention provides a method of manufacturing the above-described nitride based compound semiconductor light emitting device. The method of manufacturing the nitride based compound semiconductor light emitting device includes a step of layering at least an n-type nitride based compound semiconductor layer, an active layer, and a p-type nitride based compound semiconductor layer in this order on a second substrate to form a nitride based compound semiconductor layer part, a step of adhering a first substrate having a through hole in which a metal film is buried to the above-described nitride based compound semiconductor part, and a step of removing the above-described second substrate.

Here, the step of adhering the above-described first substrate preferably includes a step of bonding a first adhesive layer belonging to the above-described first substrate and a second adhesive layer belonging to the above-described nitride based compound semiconductor part.

The first substrate is preferably produced through the following steps:

(I) a step of forming the first adhesive layer on one face of a substrate;

(II) a step of forming a through hole on the other face of the substrate; and

(III) a step of forming a metal film in the through hole.

Alternatively, the first substrate may be produced through the following steps:

(i) a step of forming a hole with a depth such that the hole does not penetrate through the substrate on one face of the substrate;

(ii) a step of forming a metal film in the hole;

(iii) a step of grinding or polishing the other face of the substrate; and

(iv) a step of forming the first adhesive layer on either face of the substrate.

The above-described metal film is preferably formed with electrolytic plating, electroless plating, vapor deposition, sputter, printing, or a combination of two or more thereof.

The method of manufacturing the nitride based compound semiconductor light emitting device may further have a step of performing a chip division. In this case, the chip division is preferably performed at any position in a region where the above-described through hole is not formed in the above-described first substrate.

According to the present invention, a nitride based compound semiconductor light emitting device having a structure that is capable of taking out electrodes from above and below and has improved heat dissipation properties can be provided since a substrate that can easily dissipate generated heat is used in the light emitting device. The nitride based compound semiconductor light emitting device in the present invention can be preferably used for a large current use.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view showing one preferred example of a nitride based compound semiconductor light emitting device in the present invention.

FIGS. 2A to 2K are schematic process views showing one preferred example of a method of manufacturing a nitride based compound semiconductor light emitting device.

FIGS. 3A to 3F are schematic process views showing another preferred method of manufacturing a first substrate.

FIG. 4 is a schematic cross-sectional view showing another preferred example of the first substrate.

FIG. 5 is a schematic cross-sectional view showing a structure of the conventional nitride based compound semiconductor light emitting device.

### DESCRIPTION OF THE PREFERRED EMBODIMENTS

### <Nitride Based Compound Semiconductor Light Emitting Device>

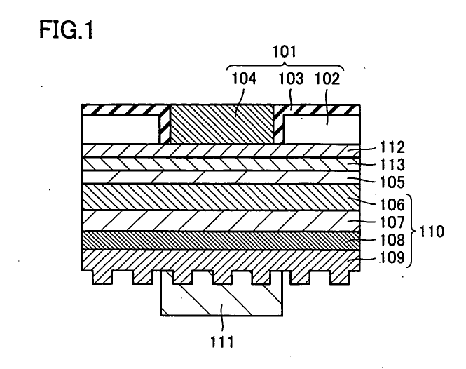

FIG. 1 is a schematic cross-sectional view showing one preferred example of a nitride based compound semiconductor light emitting device in the present invention. The nitride based compound semiconductor light emitting device shown in FIG. 1 is provided with a p-type ohmic electrode 105, a p-type nitride based semiconductor contact layer 106, a p-type nitride based semiconductor layer 107, an active layer 108, and an n-type nitride based compound semiconductor layer 109 on a first substrate 101 in this order from the side of first substrate 101. P-type nitride based semiconductor contact layer 106, p-type nitride based semiconductor layer 107, active layer 108, and n-type nitride based compound semiconductor layer 109 constitute a nitride based compound semiconductor part 110. Further, there is an n-type ohmic electrode 111 on n-type nitride based compound semiconductor layer 109. First substrate 101 and nitride based compound semiconductor part 110 are adhered to each other through a first adhesive layer 112 and a second adhesive layer 113.

First substrate 101 has a structure in which a through hole is provided on a conductive substrate 102 in the up and down direction (thickness direction) of the substrate, a metal film 104 is buried in the through hole. Further, first substrate 101 has a protective layer 103 between the inner wall surface of the through hole and the sidewall surface of metal film layer 104 and on the surface of conductive substrate 102 at the opposite side where nitride based compound semiconductor part 110 is formed.

In the nitride based compound semiconductor light emitting device of the present invention, a substrate is used in which a metal film is buried, as described above, and therefore the thermal conductivity and the electrical conductivity of the substrate can be improved on the whole. Accordingly, the heat dissipation properties from the substrate side is higher than that of the conventional substrate, and deterioration in chip reliability, a decrease in light emitting efficiency, and the like due to low heat dissipation properties can be prevented. Such a nitride based compound semiconductor light emitting device in the present invention can be preferably applied for large current use, for example.

The first substrate is explained in detail. First substrate 101 has a structure in which metal film 104 is buried in a through hole provided in conductive substrate 102 and penetrating through first substrate in the up and down direction (thickness direction). The substrate in which the through hole is provided does not necessarily have conductivity properties. However, considering stability of the substrate during formation of the trough hole, the substrate preferably has conductivity properties. As the substrate having conductivity properties, Si, GaAs, GaP, InP, SiC, or the like, can be preferably used. Considering easiness of the formation of the trough hole, a Si substrate or the like is more preferable. As described later, first substrate 101 plays a role of maintaining nitride based compound semiconductor part 110 after removing a growth substrate (second substrate) for growing nitride based compound semiconductor part 110 having a thickness of a few μm, for example. Therefore, in order to stabilize a wafer handling in a step flow after removing the growth substrate, the thickness of first substrate 101 is preferably set to be about 10 to 500 μm, and more preferably about 50 to 200 μm. The thickness of the first substrate has the same meaning as the thickness of conductive substrate102. However, as the case shown in FIG. 1, it is the total of the thickness of conductive substrate 102 and the thickness of protective layer 103 in the case of forming protective layer 103 on conductive substrate 102.

Further, the first substrate is not limited to a substrate having conductivity properties, and may be a substrate having nonconductivity properties. In the case of using a substrate having nonconductivity properties for the first substrate, electrodes can be installed on both of the main surface and the opposite surface of the nitride based compound semiconductor light emitting device even while keeping the first substrate. Examples of a material constituting the first substrate having nonconductivity properties include, for example, sapphire, AlN and the like.

Because it is considered that the thermal conductivity properties and the electrical conductivity properties of the substrate improve by forming a metal film compared with the case that the metal film is not formed, the type of a metal material constituting metal film 104 is not especially limited in the present invention. However, for further improvement of the heat dissipation properties of the substrate, as a metal film material, one having a higher thermal conductivity and electrical conductivity than the material constituting the first substrate, that is, the material of conductive substrate 102 is preferably selected. Examples of a metal having relatively high thermal conductivity and electrical conductivity include, for example, Cu, Ag, Au, Ni, Pd, Al, and the like, and one type or two types or more of these can be used in the present invention. Examples of a method of forming metal film 104 in the through hole are electrolytic plating, electroless plating, vapor deposition, sputter, printing, or a combination of two or more of these. In the case that the thickness of metal film 104 is 100 μm or more for example, the electrolytic plating method is preferably used.

The thickness of first substrate 101 is preferably the same as or larger than the thickness of metal film 104. Therefore, because the thickness of the part of the first substrate where the through hole is not formed becomes thicker than the thickness of the part of the first substrate where the through hole is formed, metal migration can be prevented, and the generation of defect in the market can be suppressed. Further, it becomes possible to protect the sidewall of the metal film formed in the through hole. As described above, in the case of forming protective layer 103 on conductive substrate 102, the thickness of first substrate 101 is the total of the thickness of conductive substrate 102 and the thickness of protective layer 103.

The shape of the through hole formed in conductive substrate 102 is not especially limited, and for example, the cross-sectional shape in a direction parallel to the substrate face may be a circular shape, an elliptic shape, a square shape, and the like. The number of the through holes per chip is not especially limited. Further, the ratio of the surface area occupied by the through holes on the surface of the first substrate is preferably as large as possible from the viewpoint of heat dissipation properties. However, in the case that a warp of a wafer due to the metal film formed becomes a problem, by forming a plurality of through holes having a smaller size, the warp of the wafer can be decreased, and at the same time, improvement of the thermal conductivity and the electrical conductivity can be attempted.

In the present invention, as shown in FIG. 1, protective layer 103 is preferably provided at least between the inner wall surface of the through hole and the sidewall surface of metal film 104. Thus, in the case of using a diffusible metal such as Cu for example, the diffusion of the metal into conductive substrate 102 can be prevented, and the chip reliability can be improved. The nitride based compound semiconductor light emitting device shown in FIG. 1 has a protective layer on the surface of conductive substrate 102 at an opposite side where nitride based compound semiconductor part 110 is formed. However, the protective layer is not necessarily formed on this part. By keeping the protective layer on the surface of the conductive substrate, a simplification of the manufacturing steps can be attempted.

The thickness of protective layer 103 is not especially limited, and can be set to be 10 to 500 nm for example. Further, as the material of the protective layer, for example, SiO₂ or SiN, a layered body of these, or a metal layer having a barrier effect toward the metal film formed in the through hole can be used.

Each of p-type nitride based semiconductor contact layer 106, p-type nitride based semiconductor layer 107, active layer 108, and n-type nitride based compound semiconductor layer 109 consists of InₓAl_{y}Ga_{1-x-y}N (0≦x, 0≦y, x+y≦1), and can be made to have a conventionally known appropriate structure and thickness. Active layer 108 is preferably made to have a multi quantum well structure (MQW). Further, a conventionally known material and structure can be adopted for p-type ohmic electrode 105 and n-type ohmic electrode 111. Hf/Al is preferably used for n-type ohimic electrode 111.

Here, n-type nitride based compound semiconductor layer 109 preferably has unevenness on at least a part of its surface. Therefore, the light radiated from active layer 108 can be taken out effectively to the outside of the nitride based compound semiconductor. The surface unevenness can be formed with dry etching, wet etching using KOH, and the like, nano-imprinting, and the like. The depth of the surface unevenness can be set to be about 0.1 to 2.0 μm for example. Further, in the case that n-type nitride based compound semiconductor layer 109 has surface unevenness, n-type ohmic electrode 111 may be formed on the surface unevenness, or may be formed on the surface where the unevenness is not formed. In order to obtain the above-described effect due to the formation of the surface unevenness, n-type nitride based compound semiconductor layer 109 preferably has unevenness on the surface other than the region where n-type ohmic electrode 111 is formed.

First adhesive layer 112 and second adhesive layer 113 are provided to adhere first substrate 101 and nitride based compound semiconductor part 110, and a conventionally known material and structure can be adopted.

The method of manufacturing the nitride based compound semiconductor light emitting device in the present invention is not especially limited. However, the method shown below can be preferably used.

<Method of Manufacturing Nitride Based Compound Semiconductor Light Emitting Device>

The method of manufacturing a nitride based compound semiconductor in the present invention includes at least the following steps:

(1) a first step of layering at least an n-type nitride based compound semiconductor layer, an active layer, and a p-type nitride based compound semiconductor layer on a second substrate in this order to form a nitride based compound semiconductor part;

(2) a second step of adhering a first substrate having a through hole in which a metal film is buried to the nitride based compound semiconductor part; and

(3) a third step of removing the above-described second substrate.

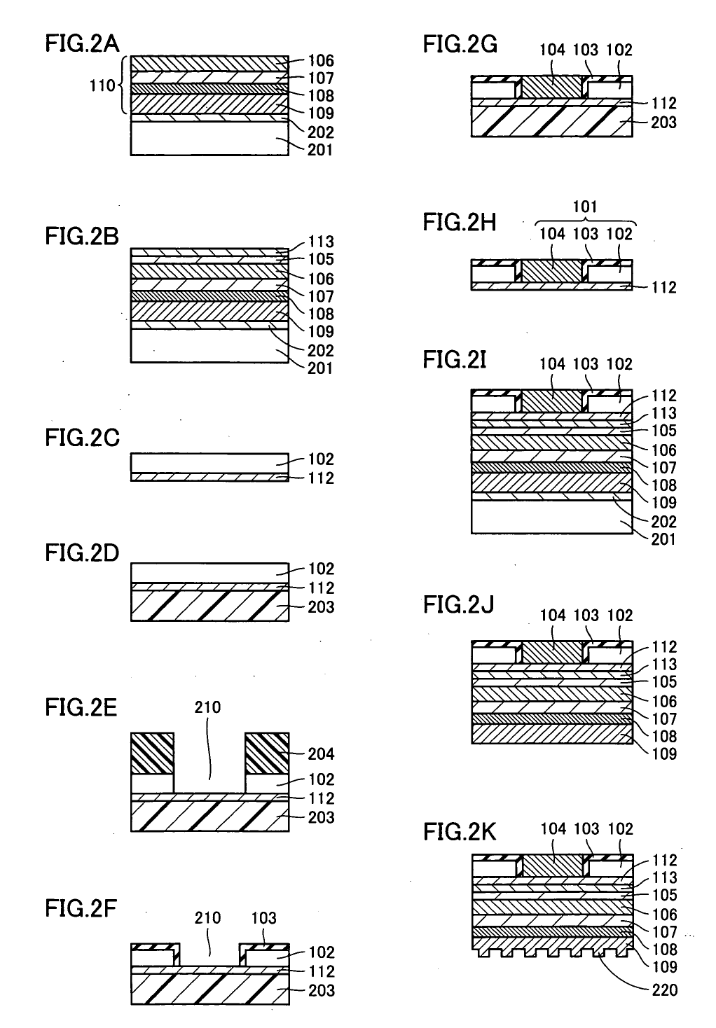

With reference to FIGS. 2A to 2K, one example of the method of manufacturing the nitride based compound semiconductor light emitting device shown in FIG. 1 is explained in detail. FIGS. 2A to 2K are schematic process views showing one preferred example of the method of manufacturing the nitride based compound semiconductor light emitting device in the present invention.

(1) First Step

In the present step, as shown in FIG. 2A, a wafer in which nitride based compound semiconductor part 110 formed is obtained by layering a buffer layer 202 on a second substrate 201 using an MOCVD method (metal organic chemical vapor deposition method) and then layering n-type nitride based compound semiconductor layer 109, active layer 108, p-type nitride based compound semiconductor layer 107, and p-type nitride based semiconductor contact layer 106 in this order. Next, after taking out the wafer from an MOCVD apparatus, as shown in FIG. 2B, p-type ohmic electrode 105 is layered on p-type nitride based semiconductor contact layer 106, and second adhesive layer 113 is further layered thereon. A layered body in which, for example, a Pd layer (layer thickness: 15 angstrom), an Ag layer (layer thickness: 300 nm), and an Ni layer (layer thickness: 100 nm) are layered in this order can be used as p-type ohmic electrode 105. However, the electrode structure and the layer thickness are not limited to this layered body. For example, an Ni layer, a Pt layer, and the like, can be used instead of the Pd layer, and an AgNd layer, an APC layer, and the like, can be used instead of the Ag layer. Further, a layered body in which a Ti layer (layer thickness: 2000 angstrom), a Pt layer (layer thickness: 300 angstrom), and an Au layer (layer thickness: 3000 angstrom) are layered in this order can be used as second adhesive layer 113. However, the structure and the layer thickness are not limited to this layered body. For example, a layered body in which a Ti layer (layer thickness: 250 angstrom), a TiW layer (layer thickness: 2000 angstrom), and an Au layer (layer thickness: 3000 angstrom) are layered in this order can be used. A sapphire substrate, and the like, can be used for example as second substrate 201.

(2) Second Step

The present step is a step of adhering a first substrate having a through hole in which a metal film is buried to the above-described nitride based compound semiconductor part. First substrate 101 can be produced as follows for example. First, with reference to FIG. 2C, a SiO₂ layer (layer thickness: 1 μm), a TiW layer (layer thickness: 2000 angstrom), an Au layer (layer thickness: 3 μm), and an AuSn layer (layer thickness: 1000 angstrom) are layered on conductive substrate 102 in order as first adhesive layer 112. Here, the SiO₂ layer functions as an etching stop layer during etching for the formation of the through hole. The top layer of first adhesive layer 112 is the AuSn layer. The structure and the layer thickness of first adhesive layer 112 are not limited to this. For example, the adhesive layer can have a configuration in which a SiO₂ layer (layer thickness: 1 μm), a Ti layer (layer thickness: 250 angstrom), a TiW layer (layer thickness: 2000 angstrom), an Au layer (layer thickness: 3 μm), and an AuSn layer (layer thickness: 1000 angstrom) are layered in order. Further, the substrate that is used as the first substrate does not necessarily have conductivity properties as described above. However, the substrate preferably has conductivity properties.

Further, the thickness of conductive substrate 102 is preferably about 10 to 500 μm, and is, for example, 100 μm. The material of conductive substrate 102 is as described above, and for example a Si substrate may be used.

Next, as shown in FIG. 2D, a support material 203 is provided on first adhesive layer 112. For example, an UV tape (a resin tape that can be decomposed by UV radiation), and the like, can be used as support material 203. Because only first adhesive layer 112 keeps the substance in the through hole formation region after the through hole is provided in conductive substrate 102, support material 203 plays a support role to keep the substrate. In addition, a photo mask 204 is formed on the opposite side of the surface where first adhesive layer 112 is formed, and then a through hole 210 penetrating through conductive substrate 102 is formed by dry etching as shown in FIG. 2E. The thickness of photo mask 204 is preferably 10 μm or more. In the case of forming a through hole in a Si substrate, an Al film may be used as a mask during etching instead of using the photo resist mask.

Next, removal of a SiO₂ layer and a TiW layer that are located in the bottom surface of through hole 210 and that are constitutional films of exposed first adhesive layer 112 is preformed by dry etching. An Au layer is exposed by the removal of the SiO₂ layer and the TiW layer. In the case of performing the formation of the metal film by electrolytic plating described later, the Au layer functions as a seed of the electrolytic plating. In the case of forming the metal film with a method other than electrolytic plating, the removal of the SiO₂ layer and the TiW layer is not always necessary.

Next, as shown in FIG. 2F, a SiO₂ film (layer thickness: 4000 angstrom) and a SiN film (layer thickness: 5000 angstrom) as protective layer 103 are formed in order on the side surface of through hole 210 and the surface of conductive substrate 102 after removing photo mask 204 using a peeling liquid. Further, a metal layer having a barrier effect toward metal film 104 can be used as the protective layer, and examples of such a metal layer include a Ti layer, a TiN layer, a TaN layer, TiW layer, and the like. The thickness of the metal layer can be set to be about 2000 angstrom for example.

Next, with reference to FIG. 2G, metal film 104 is formed in through hole 210. In the case of forming metal film 104 by electrolytic plating, the formation of the metal film is performed by immersing the substrate in an electrolytic plating bath. The immersing time is not especially limited, is appropriately selected depending on the uniformity of the thickness in the wafer and the film quality that are required for the metal film, and can be set to be about 30 to 180 minutes for example. More specifically, in the case of forming a metal film of 100 μm thickness for example, the immersing time can be set to be about 90 minutes. As described above, the thickness of metal film 104 is preferably the same as or smaller than the thickness of first substrate 101. Therefore, the thickness of the first substrate (the total of the thickness of conductive substrate 102 and the thickness of protective layer 103 in the case of the nitride based compound semiconductor light emitting device in FIG. 1) is 100 μm, and the thickness of the metal film can be preferably set to be 100 μm or less. When the metal film is formed, in the case that the thickness of the metal film becomes larger than the thickness of the first substrate and the metal film is projecting from the surface of the first substrate, the thickness of the metal film can be preferably set to be the thickness of the substrate or less by polishing, or the like.

Next, support material 203 is removed with UV radiation, and first substrate 101 having first adhesive layer on one surface and the metal film in the through hole is obtained (see FIG. 2H).

A device having a structure shown in FIG. 21 is obtained by adhering first substrate 101 having first adhesive layer 112 formed as above with nitride based compound semiconductor part 110 having second adhesive layer 113 and formed on second substrate 201. At this time, in the case that the top layer of first adhesive layer 112 is made to be an AuSn layer and the top layer of second adhesive layer 113 is made to be an Au layer, an AuSn eutectic bonding can be used in the above-described adhesion.

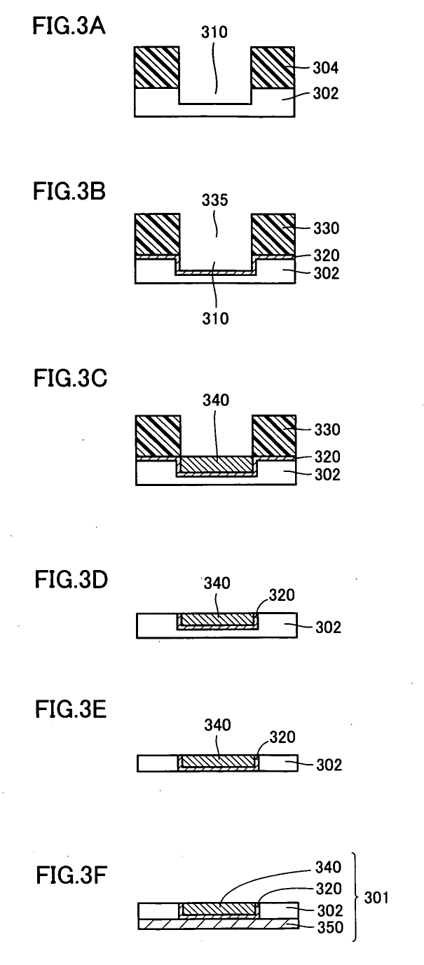

Further, the first substrate may be a substrate produced with a method shown as follow. With reference to FIGS. 3A to 3F, another preferred method of manufacturing the first substrate is explained. First, as shown in FIG. 3A, a photo mask 304 of 1 μm or more thickness is formed on a conductive substrate 302, and then a hole 310 having a depth of not penetrating through conductive substrate 302 is formed by dry etching. For example, in the case that the thickness of conductive substrate 302 is 200 μm, the depth of hole 310 can be set to be about 100 μm. In the case that conductive substrate 302 is a Si substrate, as described above, an Al film can be used as a mask for etching.

Next, the photo mask is removed, and a step of forming a metal film 340 in hole 310 is performed. In the case of forming the metal film with an electrolytic plating method, the metal film can be formed as follows for example. First, a barrier metal layer (layer thickness: 2000 angstrom) and a seed layer (layer thickness: 3000 angstrom) are formed in order as a protective layer 320 on the surface where hole 310 was formed. Examples of the barrier metal layer include a Ti layer, a TiN layer, a TiW layer, and a TaN layer, and the like. Examples of the seed layer include a Cu layer, an Au layer, and the like. Subsequently, a photo mask 330 (thickness: 1 μm or more) for electrolytic plating is formed (see FIG. 3B). Because hole 310 is formed in conductive substrate 302, a material such as a dry film for example can be preferably used as a material of photo mask 330 rather than a liquid resist. Further, patterning of the photo mask is preferably formed so as to cover a part other than hole 310 formed in conductive substrate 302 with the photo resist. That is, hole 310 formed in the conductive substrate is preferably matched with an opening 335 of photo mask 330.

Next, metal film 340 is formed in hole 310 of conductive substrate 302 by electrolytic plating (see FIG. 3C). The electrolytic plating can be performed by immersing the substrate in an electrolytic plating bath. The immersing time is not especially limited, is appropriately selected depending on the uniformity of the thickness in the wafer and the film quality that are required for the metal film, and can be set to be about 30 to 180 minutes for example. More specifically, in the case of forming a metal film of 100 μm thickness for example, the immersing time can be set to be about 90 minutes. In the case of forming metal film 340 with a method other than electrolytic plating, it is preferable to have a metal layer having a barrier effect at least toward metal film 340 between the inner wall surface of hole 310 and the sidewall surface of metal film 340. Next, photo mask 330 is removed using a peeling liquid.

Then, protective layer 320 on the surface of conductive substrate 302 is removed by etching or polishing (see FIG. 3D). In the case that the metal film projects from the surface of the conductive substrate, the thickness of the metal film is preferably made to be the thickness of the conductive substrate while removing the protective layer by polishing, or the like.

Next, protective layer 320 is exposed by grinding or polishing the surface of the conductive substrate at an opposite side where hole 310 is formed (see FIG. 3F). Therefore, the through hole is formed in the conductive substrate, and the first substrate having a structure in which the metal film is buried in the through hole is obtained. In this example, the thickness of metal film 340 is 100 μm. The grinding or the polishing may be performed until metal film 340 is exposed. Finally, as shown in FIG. 3F, a first adhesive layer 350 is formed on the ground or polished surface for the bonding with nitride based compound semiconductor part 110. First adhesive layer 350 may be formed on the surface opposite to the ground or polished face. First adhesive layer 350 can have a configuration in which a TiW layer (layer thickness: 2000 angstrom), an Au layer (layer thickness: 3 m), and an AuSn layer (layer thickness: 1000 angstrom) are layered in order for example. For example, a Ti layer can be used instead of the TiW layer.

A device having the structure similar to the structure shown in FIG. 21 can be obtained by adhering first substrate 301 having first adhesive layer 350 formed above with nitride based compound semiconductor part 110 having the second adhesive layer and formed on second substrate 201. At this time, in the case that the top layer of first adhesive layer 350 is made to be an AuSn layer and the top layer of second adhesive layer 113 is made to be an Au layer, AuSn eutectic bonding can be used in the above-described adhesion.

(3) Third Step

The present step is a step of removing second substrate 201 to expose the surface of n-type nitride based compound semiconductor layer 109. Specifically, the surface of n-type nitride based compound semiconductor layer 109 is exposed by removing second substrate 201 by laser peeling, removing Ga by performing hydrochloric acid based wet etching or the like on buffer layer 202, and then performing dry etching. Thus, a device in which second substrate 201 is removed as shown in FIG. 2J is obtained. Here, the nitride based compound semiconductor part having a thickness of a few μm can be maintained by first substrate 101 even after second substrate 201 is removed, and wafer handling in the subsequent steps can be stabilized.

Next, a resist mask (for example, 1 μm thick) is formed on the surface of n-type nitride based compound semiconductor layer 109, and a surface unevenness 220 of 1 μm depth for example is formed by dry etching (see FIG. 2K). After the dry etching, removal of the resist is performed with a peeling liquid. Next, the nitride based compound semiconductor light emitting device in FIG. 1 is obtained by forming n-type ohmic electrode 111, and then performing the chip division. N-type ohmic electrode 111 can have a structure in which an Hf layer (50 angstrom) and an Al layer (9000 angstrom) are layered one by one. The structure and the thickness of n-type ohmic electrode 111 are not limited to this. Further, the chip division is preferably performed at any position in a region where the through hole is not formed, that is, a region where the metal film is not formed. The chip division at a position where the metal film is formed causes deterioration of metal film deterioration because the side face of the metal film is not protected and it becomes a condition in which the metal film is exposed. Further, because the total surface area of the metal film per chip decreases, there is a fear that the heat dissipation properties decrease. The chip division can be performed by dicing.

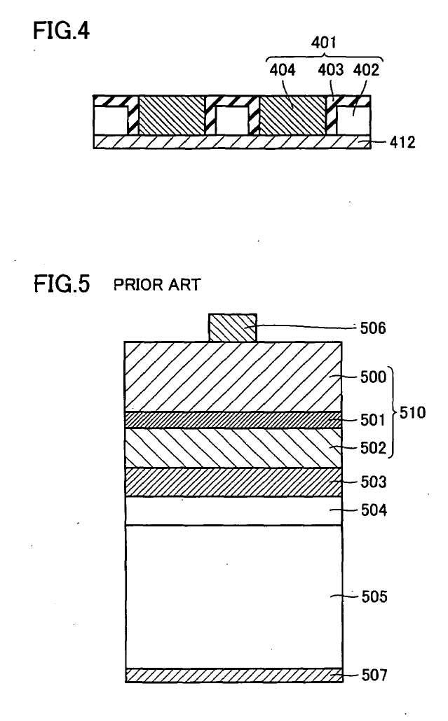

The nitride based compound semiconductor light emitting device shown in FIG. 1 has one through hole per chip. However, it is not limited to this, and in the case that the warp of the wafer becomes a problem, etc., the warp of the wafer can be improved and at the same time, improvement of the electrical conductivity and the thermal conductivity can be attempted by using a first substrate 401 in which a plurality of through holes with a smaller size (width of the through hole) are formed. First substrate 401 shown in FIG. 4 is provided with a metal film 404 buried in two through holes formed in a conductive substrate 402 and a protective layer 403 formed between the inner wall surface of the through hole and the sidewall surface of metal film 404 and on the surface opposite to the side where the nitride based compound semiconductor part of a conductive substrate 402 is formed. Further, first adhesive layer 412 is formed on the surface of first substrate 401.

Because the nitride based compound semiconductor light emitting device in the present invention has a structure that is capable of taking out electrodes from above and below and has high heat dissipation properties, it can be preferably applied to products in which high heat dissipation is necessary, products for large current use etc. for example, and deterioration of reliability and a decrease of light emitting efficiency can be prevented.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A nitride based compound semiconductor light emitting device comprising a first substrate and a nitride based compound semiconductor part including a p-type nitride based compound semiconductor layer, an active layer, and an n-type nitride based compound semiconductor layer in this order from said first substrate side, wherein said first substrate has a through hole penetrating through said first substrate in up and down directions, and a metal-film is buried in said through hole.

2. The nitride based compound semiconductor light emitting device according to claim 1, wherein each of the electrical conductivity and the thermal conductivity of said metal film is larger than the electrical conductivity and the thermal conductivity of the material constituting said first substrate.

3. The nitride based compound semiconductor light emitting device according to claim 1, wherein said metal film is constituted from one kind or two kinds or more of metals selected from the group consisting of Cu, Ag, Au, Ni, Pd, and Al.

4. The nitride based compound semiconductor light emitting device according to claim 1, wherein said first substrate has conductivity properties.

5. The nitride based compound semiconductor light emitting device according to claim 4, wherein said first substrate formed of a material selected from the group consisting of Si, GaAs, GaP, InP, and SiC.

6. The nitride based compound semiconductor light emitting device according to claim 1, wherein said first substrate has nonconductivity properties.

7. The nitride based compound semiconductor light emitting device according to claim 1, wherein the thickness of said first substrate is 10 to 500 μm.

8. The nitride based compound semiconductor light emitting device according to claim 1, wherein the thickness of said first substrate is same as or thicker than the thickness of said metal film.

9. The nitride based compound semiconductor light emitting device according to claim 1 having a protective layer at least between the inner wall surface of said through hole and the sidewall surface of said metal film.

10. The nitride based compound semiconductor light emitting device according to claim 1, wherein said n-type nitride based compound semiconductor layer has unevenness at least on one part of its surface.

11. The nitride based compound semiconductor light emitting device according to claim 1 having an n-type electrode on the surface of said n-type nitride based compound semiconductor layer.

12. A method of manufacturing the nitride based compound semiconductor light emitting device according to claim 1 comprising the steps of:
layering at least an n-type nitride based compound semiconductor layer, an active layer, and a p-type nitride based compound semiconductor layer in this order on a second substrate to form a nitride based compound semiconductor layer part;
adhering the first substrate having a through hole and in which a metal film is buried in said through hole to said nitride based compound semiconductor part; and
removing said second substrate.

13. The method of a nitride based compound semiconductor light emitting device according to claim 12, wherein the step of adhering said first substrate includes a step of bonding a first adhesive layer belonging to said first substrate and a second adhesive layer belonging to said nitride based compound semiconductor part.

14. The method of a nitride based compound semiconductor light emitting device according to claim 13, wherein said first substrate is produced through the following steps of:
(I) forming a first adhesive layer on one face of a substrate;
(II) forming a through hole on the other face of the substrate; and
(III) forming a metal film in the through hole.

15. The method of a nitride based compound semiconductor light emitting device according to claim 13, wherein said first substrate is produced through the following steps of:
(i) forming a hole with a depth such that the hole does not penetrate through the substrate on one face of the substrate;
(ii) forming a metal film in the hole;
(iii) grinding or polishing the other face of the substrate; and
(iv) forming a first adhesive layer on any face of the substrate.

16. The method of a nitride based compound semiconductor light emitting device according to claim 12, wherein said metal film is formed with electrolytic plating, electroless plating, vapor deposition, sputter, printing, or a combination of two or more of these.

17. The method of a nitride based compound semiconductor light emitting device according to claim 12 further comprising a step of performing a chip division, wherein the chip division is performed at any position in a region where said through hole is not formed in said first substrate.
